(19) United States
(12) Patent Application Publication
(10) Pub. No.: US 2024/0347631 A1
(43) Pub. Date: Oct. 17, 2024

(54) SEMICONDUCTOR DEVICE

(71) Applicant: Samsung Electronics Co., Ltd., Suwon-si (KR)

(72) Inventors: Seonhaeng LEE, Suwon-si (KR); DONGHEE SON, Suwon-si (KR)

(21) Appl. No.: 18/509,483

(22) Filed: Nov. 15, 2023

(30) Foreign Application Priority Data
Apr. 14, 2023 (KR) 10-2023-0049512

(51) Int. Cl. H01L 29/78; H10B 12/00

(52) U.S. Cl. CPC H01L 29/7831; H10B 12/482; H10B 12/485; H10B 12/488

(57) ABSTRACT

A semiconductor device includes an outer active pattern on a substrate, the outer active pattern having a trench crossing the outer active pattern, an outer word line covering a wall of the trench, an inner active pattern covering the outer word line in the trench, an inner word line covering the inner active pattern in the trench, and a separation insulating pattern interposed between the outer word line and the inner active pattern in the trench. The outer word line and the inner word line are insulated from each other.

### CROSS-REFERENCE TO RELATED APPLICATIONS

This U.S. non-provisional patent application claims priority under 35 U.S.C. § 119 to Korean Patent Application No. 10-2023-0049512, filed on Apr. 14, 2023, in the Korean Intellectual Property Office, the entire contents of which are hereby incorporated by reference.

### BACKGROUND OF THE INVENTION

The present disclosure relates to a semiconductor device, and more particularly, relates to a semiconductor device including a multi-gate structure.

Semiconductor devices have an important role in an electronic industry because of their small size, multi-functionality, and/or low fabrication cost. Semiconductor devices may be categorized as one of semiconductor memory devices storing logic data, semiconductor logic devices processing operations of logic data, and hybrid semiconductor devices having both memory and logic elements.

Recently, high speed and low consumption of electronic products require that semiconductor devices embedded in the electronic products should have high operating speed and/or lower operating voltage Therefore, to satisfy these required characteristics, semiconductor devices are highly integrated, and various studies have been conducted for this purpose.

### SUMMARY

An object of the present disclosure is to provide a semiconductor device with improved integration.

An object of the present disclosure is to provide a semiconductor device with improved electrical characteristics.

The problems solved by embodiments of the invention are not limited to the above-mentioned problems, and other benefits not mentioned will be clearly understood by those skilled in the art from the following description.

A semiconductor device according to some embodiments of the present disclosure may include an outer active pattern on a substrate with the outer active pattern having a trench crossing the active pattern, an outer word line covering a wall of the trench, an inner active pattern covering the outer word line in the trench, an inner word line covering the inner active pattern in the trench, and a separation insulating pattern interposed between the outer word line and the inner active pattern in the trench. The outer word line and the inner word line may be insulated from each other. The outer word line may include an outer gate electrode between the outer active pattern and the separation insulating pattern and an outer dielectric pattern between the outer gate electrode and the outer active pattern. The inner word line may include an inner gate electrode covering the inner active pattern in the trench and an inner dielectric pattern between the inner gate electrode and the inner active pattern. The outer active pattern may be spaced apart from the outer gate electrode with the outer dielectric pattern therebetween. The inner active pattern may be spaced apart from the inner gate electrode with the inner dielectric pattern interposed therebetween.

A semiconductor device according to some embodiments of the present disclosure may include an outer active pattern on a substrate with the outer active pattern having a trench crossing the outer active pattern, an outer word line covering a wall of the trench, an inner active pattern covering the outer word line in the trench, an inner word line covering the inner active pattern in the trench, a separation insulating pattern interposed between the outer word line and the inner active pattern in the trench, an outer bit line and an outer data storage pattern electrically connected to the outer active pattern, respectively, and an inner bit line and an inner data storage pattern electrically connected to the inner active pattern. The outer active pattern may include a pair of outer source/drain regions thereon. The inner active pattern may include a pair of inner source/drain regions thereon. The outer bit line may be electrically connected to one of the pair of outer source/drain regions. The inner bit line may be electrically connected to one of the pair of inner source/drain regions.

A semiconductor device according to some embodiments of the present disclosure may include a first active pattern on a substrate, a second active pattern on the first active pattern, a separation insulating pattern between the first active pattern and the second active pattern, a first word line between the first active pattern and the separation insulating pattern, and a second word line on the second active pattern. The first word line and the second word line are insulated from each other. The first word line includes a first gate electrode between the first active pattern and the separation insulating pattern and a first dielectric pattern between the first active pattern and the first gate electrode. The second word line includes a second gate electrode on the second active pattern and a second dielectric pattern between the second active pattern and the second gate electrode. A thickness of the separation insulating pattern is greater than or substantially equal to a thickness of the first dielectric pattern and a thickness of the second dielectric pattern, respectively.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a view illustrating a semiconductor device according to some embodiments of the present disclosure.

FIG. 2 is a plan view illustrating a semiconductor device according to some embodiments of the present disclosure.

FIG. 3 is a cross-sectional view corresponding to line A-A′ in FIG. 2.

FIGS. 4A and 4B are cross-sectional views corresponding to line A-A′ of FIG. 2.

FIGS. 5 to 13 are plan views illustrating semiconductor devices according to some embodiments of the present disclosure.

### DETAILED DESCRIPTION

The present disclosure now will be described more fully hereinafter with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

Items described in the singular herein may be provided in plural, as can be seen, for example, in the drawings. Thus, the description of a single item that is provided in plural should be understood to be applicable to the remaining plurality of items unless context indicates otherwise.

It will be understood that when an element is referred to as being “connected” or “coupled” to or “on” or “provided on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

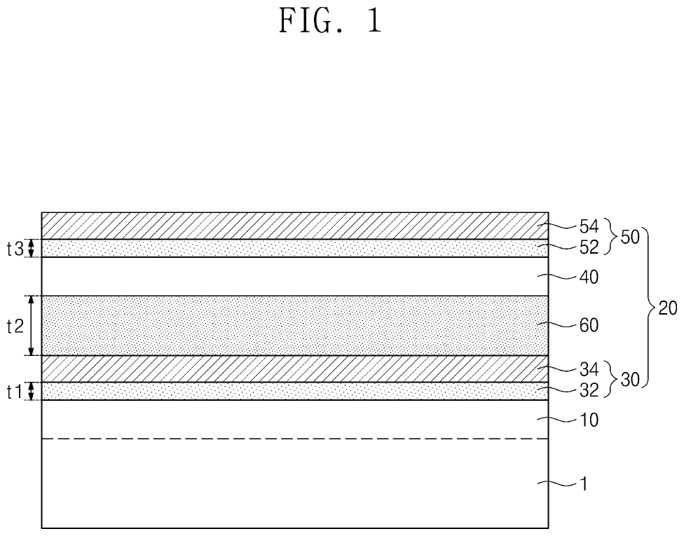

FIG. 1 is a view illustrating a cross-section of an active region of a semiconductor device according to some embodiments of the present disclosure.

Referring to FIG. 1, a substrate 1 may be provided. The substrate 1 may be formed of and/or include a semiconductor material. For example, the substrate 1 may be formed of and/or include at least one of single crystal silicon, polysilicon, an oxide semiconductor material (e.g., InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO and InxGayO, etc.), a two-dimensional material (e.g., graphene), and transition metal dichalcogenide (TMD) including a transition metal element (Mo, W, V, Nb, Ta, Ti, etc.) and a chalcogen element (S, Se, Te, etc.). The substrate 1 may be formed of a single material or may include two or more materials.

A first active pattern 10 may be provided on the substrate 1. For example, the first active pattern 10 may be a portion (e.g., upper portion) of the substrate 1. The portion of the substrate 1 corresponding to the first active pattern 10 may be formed by removing upper portions of the substrate 1 in areas other than the first active portion 10 leaving the upper portion to form the first active portion 10. In the following description, further reference to the substrate 1 r will refer to a remaining portion of the substrate 1 that excludes the first active pattern 10. The first active pattern 10 may be formed of and/or include a semiconductor material.

A multi-gate structure 20 may be provided on the first active pattern 10. The multi-gate structure 20 may include a first word line 30, a second active pattern 40, a second word line 50, and a separation insulating pattern 60. For example, the first word line 30, the separation insulating pattern 60, the second active pattern 40, and the second word line 50 may be sequentially provided on the first active pattern 10. Elements that are sequentially provided may be elements that are provided in a sequential order with each additional element being added on the previously provided elements. In the example of FIG. 1, the elements may be sequentially provided in a vertical direction from a lowermost element to an uppermost element. In other examples, elements may be sequentially provided in other orientations such as horizontally such that the elements are sequentially provided from left to right or right to left. In another example, elements may be sequentially provided in layers to cover a surface that may have horizontal and vertical portions and the layers may be provided sequentially from an outermost layer to an innermost layer where the outermost layer refers to a layer that is nearest the surface being covered.

The first word line 30 may be provided on the first active pattern 10. The first word line 30 may control a first channel region within the first active pattern 10. The first word line 30 may include a first dielectric pattern 32 on the first active pattern 10 and a first gate electrode 34 on the first dielectric pattern 32.

The first gate electrode 34 may be interposed between the first active pattern 10 and the separation insulating pattern 60. The first gate electrode 34 may be formed of and/or include a conductive material. For example, the first gate electrode 34 may be formed of and/or include a metal material (e.g., Ti, Mo, W, Cu, Al, Ta, Ru, Ir, etc.).

The first dielectric pattern 32 may be interposed between the first active pattern 10 and the first gate electrode 34. The first dielectric pattern 32 may be formed of and/or include an insulating material. For example, the first dielectric pattern 32 may be formed of and/or include at least one of silicon oxide, silicon nitride, silicon oxynitride, and a high-k material. In this specification, a high-k material is defined as a material having a higher dielectric constant than the dielectric constant of silicon oxide.

The second active pattern 40 may be provided on the first word line 30. The second active pattern 40 may be formed of and/or include a semiconductor material. For example, the second active pattern 40 may be formed of and/or include at least one of single crystal silicon, polysilicon, an oxide semiconductor material (e.g., InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO and InxGayO, etc.), a two-dimensional material (e.g., graphene), and transition metal dichalcogenide (TMD) including a transition metal element (Mo, W, V, Nb, Ta, Ti, etc.) and a chalcogen element (S, Se, Te, etc.).

The second word line 50 may be provided on the second active pattern 40. The second word line 50 may control a second channel region within the second active pattern 40. The second word line 50 may be insulated from the first word line 30. The second word line 50 may be interposed between a second dielectric pattern 52 on the second active pattern 40 and a second gate electrode 54 on the second dielectric pattern 52.

The second gate electrode 54 may be formed of and/or include a conductive material. For example, the second gate electrode 54 may be formed of and/or include a metal material (e.g., Ti, Mo, W, Cu, Al, Ta, Ru, Ir, etc.).

The second dielectric pattern 52 may be interposed between the second active pattern 40 and the second gate electrode 54. The second dielectric pattern 52 may be formed of and/or include an insulating material. For example, the second dielectric pattern 52 may be formed of and/or include at least one of silicon oxide, silicon nitride, silicon oxynitride, and a high-k material.

The separation insulating pattern 60 may be interposed between the first active pattern 10 and the second active pattern 40. For example, the separation insulating pattern 60 may be interposed between the first word line 30 and the second active pattern 40. The separation insulating pattern 60 may separate and insulate the first word line 30 and the second active pattern 40 from each other. The separation insulating pattern 60 may minimize an interference effect of an electrical signal applied to the first word line 30 to the second active pattern 40. Accordingly, reliability of the semiconductor device may be improved.

The separation insulating pattern 60 may be formed of and/or include an insulating material. For example, the separation insulating pattern 60 may be formed of and/or include at least one of silicon oxide, silicon nitride, silicon oxynitride, and a low dielectric material. In this specification, a low-k material is defined as a material having a lower dielectric constant than the dielectric constant of silicon oxide.

A thickness t1 of the first dielectric pattern 32 and a thickness t2 of the second dielectric pattern 52 may be the same as or different from each other. For example, a thickness t3 of the separation insulating pattern 60 may be greater than or substantially equal to the thickness t1 of the first dielectric pattern 32 and the thickness t2 of the second dielectric pattern 52, respectively. Accordingly, the separation insulating pattern 60 may effectively insulate the first word line 30 and the second active pattern 40. However, embodiments are not limited thereto, and as another example, the thickness t3 of the separation insulating pattern 60 may be smaller than the thickness t1 of the first dielectric pattern 32 and the thickness t2 of the second dielectric pattern 52, respectively.

A third active pattern (not shown) and a third word line (not shown) may be further provided on the second word line 50. The third word line may control a third channel region of the third active pattern. An additional separation insulating pattern (not shown) may be further provided, may space the third active pattern from the second word line 50, and may insulate the third active pattern from the second word line 50. However, embodiments are not limited thereto, and additional active patterns (not shown) and additional word lines (not shown) may be further provided.

According to embodiments of the present disclosure, the first active pattern 10 and the second active pattern 40 may be controlled by different word lines which may be sequentially provided and/or stacked on one another. Accordingly, the semiconductor device may include a plurality of transistors that are sequentially stacked, and as a result, integration of the semiconductor device may be improved.

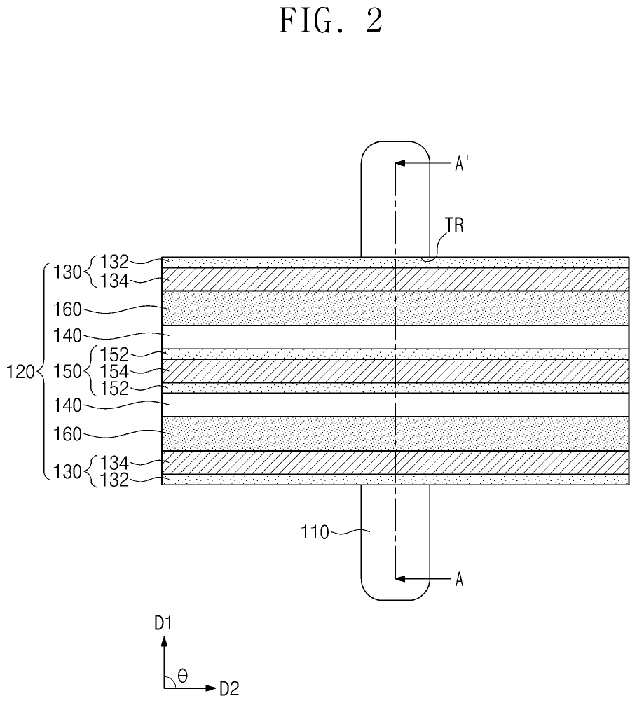

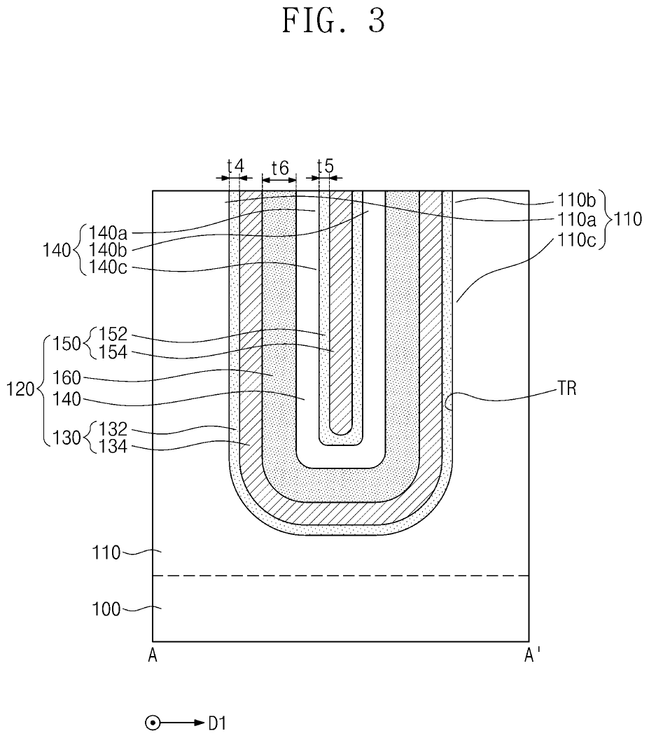

FIG. 2 is a plan view illustrating a semiconductor device according to some embodiments of the present disclosure. FIG. 3 is a cross-sectional view corresponding to line A-A in FIG. 2.

Referring to FIGS. 2 and 3, a substrate 100 may be provided. The substrate 100 may correspond to the substrate 1 described with reference to FIG. 1. Accordingly, the substrate 100 may be formed of and/or include a semiconductor material. For example, the substrate 100 may be formed of and/or include at least one of single crystal silicon, polysilicon, an oxide semiconductor material (e.g., InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO and InxGayO, etc.), a two-dimensional material (e.g., graphene), and transition metal dichalcogenide (TMD) including a transition metal element (Mo, W, V, Nb, Ta, Ti, etc.) and a chalcogen element (S, Se, Te, etc.). The substrate 100 may be formed of a single material or may include two or more materials.

An outer active pattern 110 may be provided on the substrate 100. The outer active pattern 110 may correspond to the first active pattern 10 described with reference to FIG. 1. For example, the outer active pattern 110 may be a portion (e.g., upper portion) of the substrate 100. In this embodiment, reference to the substrate 100 refers to the remaining portions of the substrate 100 excluding the outer active pattern 110. The outer active pattern 110 may be formed of and/or include a semiconductor material.

The outer active pattern 110 may include a pair of outer source/drain regions 110a and 110b and an outer channel region 110c. The pair of outer source/drain regions 110a and 110b may be provided on an upper portion of the outer active pattern 110 and may be provided adjacent to a trench TR crossing the outer active pattern 110. The outer channel region 110c may be provided between the pair of outer source/drain regions 110a and 110b and may extend along a wall of the trench TR (e.g., the outer active pattern 110 may have a trench TR with the outer source/drain regions 110a and 110b located at opposing upper edges adjacent the trench TR with the outer channel region 110c passing below the trench TR to extend between the outer source/drain regions 110a and 110b). Each of the pair of outer source/drain regions 110a and outer channel region 110c may include impurities.

A multi-gate structure 120 may cross the outer active pattern 110. The multi-gate structure 120 may correspond to the multi-gate structure 20 described with reference to FIG. 1. The multi-gate structure 120 may fill the trench TR crossing the outer active pattern 110. The trench TR and content of the trench TR may be collectively referred to as a trench region. The multi-gate structure 120 may include an outer word line 130, an inner active pattern 140, an inner word line 150, and a separation insulating pattern 160. For example, the outer word line 130, the separation insulating pattern 160, the inner active pattern 140, and the inner word line 150 may be sequentially provided on a wall of the trench TR (e.g., sequential layers beginning at a wall of the trench TR and progressing inward towards a center line of the trench TR).

The outer active pattern 110 may have a horizontal bar shape elongated in a first direction D1 parallel to a lower surface of the substrate 100. For example, the outer active pattern 110 may have a long axis extending in the first direction D1. The multi-gate structure 120 may extend in a second direction D2 that is parallel to the lower surface of the substrate 100 and intersects the first direction D1. The first direction D1 and the second direction D2 may form a first angle θ with each other, and the first angle θ may be greater than 0° and less than 90°. For example, as shown in FIG. 2, the first angle θ may be 90°.

The outer word line 130 may be provided on the wall of the trench TR and may be adjacent to the outer active pattern 110. For example, the outer word line 130 may cover the surface of the outer active pattern 110 in the trench TR. For example, the outer word line 130 may be surrounded by the outer active pattern 110 within the trench TR (e.g., surrounded in a horizontal direction such as D1). Within the trench TR, the outer word line 130 may cover and control the outer channel region 110c of the outer active pattern 110. The outer word line 130 may extend in the second direction D2 (e.g., extend beyond the outer active pattern). The outer word line 130 may include an outer dielectric pattern 132 and an outer gate electrode 134 sequentially covering the walls of the trench TR.

The outer dielectric pattern 132 may be interposed between the outer active pattern 110 and the outer gate electrode 134. For example, the outer dielectric pattern 132 may conformally cover the wall of the trench TR. The outer dielectric pattern 132 may be formed of and/or include an insulating material. For example, the outer dielectric pattern 132 may be formed of and/or include at least one of silicon oxide, silicon nitride, silicon oxynitride, and a high-k material.

The outer gate electrode 134 may be provided on an inner wall of the trench region (e.g., sequentially provided on the outer dielectric pattern 132). For example, the outer gate electrode 134 may cover the outer dielectric pattern 132 in the trench TR. For example, the outer gate electrode 134 may conformally cover the outer dielectric pattern 132. The outer gate electrode 134 may be formed of and/or include a conductive material. For example, the outer gate electrode 134 may be formed of and/or include a metal material (e.g., Ti, Mo, W, Cu, Al, Ta, Ru, Ir, etc.).

The inner active pattern 140 may be provided on an inner wall of the trench region TR (e.g., sequentially provided on the outer word line 130). For example, the inner active pattern 140 may cover the outer word line 130 in the trench TR. For example, the inner active pattern 140 may conformally cover the outer word line 130.

The inner active pattern 140 may be formed of and/or include a semiconductor material. For example, the inner active pattern 140 may be formed of and/or include at least one of single crystal silicon, polysilicon, an oxide semiconductor material (e.g., InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO and InxGayO, etc.), a two-dimensional material (e.g., graphene), and transition metal dichalcogenide (TMD) including a transition metal element (Mo, W, V, Nb, Ta, Ti, etc.) and a chalcogen element (S, Se, Te, etc.).

The inner active pattern 140 may include a pair of inner source/drain regions 140a and 140b and an inner channel region 140c. The pair of inner source/drain regions 140a and 140b may be provided on the inner active pattern 140. For example, the pair of inner source/drain regions 140a and 140b may be provided to be adjacent to both ends of the inner active pattern 140 disposed on an upper portion of the inner active pattern 140. The inner channel region 140c may be provided between the pair of inner source/drain regions 140a and 140b and may extend along an inner wall of the trench region (e.g., extend from an upper end of the trench region on a first side of the trench TR, across a lower portion of the trench region proximate the bottom of the trench TR, and back to an upper end of the trench region on a second side of the trench TR opposite the first side of the trench TR). Each the pair of inner source/drain regions 140a and 140b and the inner channel region 140c may include impurities.

The inner word line 150 may be provided on an inner wall of the trench region (e.g., sequentially provided on the inner active pattern 140). For example, the inner word line 150 may cover the inner active pattern 140 in the trench TR. For example, the inner word line 150 may be surrounded by the inner active pattern 140. The inner word line 150 may cover and control the inner channel region 140c of the inner active pattern 140. The inner word line 150 may extend in the second direction D2 (e.g., extend beyond the first active pattern 110). The inner word line 150 may include an inner dielectric pattern 152 and an inner gate electrode 154 sequentially covering inner walls of the trench region.

The inner dielectric pattern 152 may be interposed between the inner active pattern 140 and the inner gate electrode 154. For example, the inner dielectric pattern 152 may conformally cover an inner wall of the trench region TR such as an inner wall of the inner active pattern 140. The inner dielectric pattern 152 may be formed of and/or include an insulating material. For example, the inner dielectric pattern 152 may be formed of and/or include at least one of silicon oxide, silicon nitride, silicon oxynitride, and a high-k material.

The inner gate electrode 154 may be provided on an inner wall of the trench region. For example, the inner gate electrode 154 may cover the inner dielectric pattern 152 in the trench TR. For example, as shown in FIG. 3, the inter gate electrode 154 may be provided to completely fill a region surrounded by the inner dielectric pattern 152. As another example, although not shown, the inner gate electrode 154 may conformally cover the inner dielectric pattern 152. However, embodiments are not limited thereto, and the inner gate electrode 154 may be provided in various forms. The inner gate electrode 154 may be formed of and/or include a conductive material. For example, the inner gate electrode 154 may be formed of and/or include a metal material (e.g., Ti, Mo, W, Cu, Al, Ta, Ru, Ir, etc.).

The separation insulating pattern 160 may be interposed between the outer active pattern 110 and the inner active pattern 140. For example, the separation insulating pattern 160 may be interposed between the outer word line 130 and the inner active pattern 140. The separation insulating pattern 160 may separate and insulate the outer word line 130 and the inner active pattern 140 from each other. The separation insulating pattern 160 may minimize interference caused by an electrical signal applied to the outer word line 130 to the inner active pattern 140. Accordingly, reliability of the semiconductor device may be improved by the inclusion of the separation insulating pattern 160.

The separation insulating pattern 160 may be formed of and/or include an insulating material. For example, the separation insulating pattern 160 may be formed of and/or include at least one of silicon oxide, silicon nitride, silicon oxynitride, and a low-k material.

A thickness t4 of the outer dielectric pattern 132 and a thickness t5 of the inner dielectric pattern 152 may be equal to or different from each other. For example, a thickness t6 of the separation insulating pattern 160 may be greater than or substantially equal to the thickness t4 of the outer dielectric pattern 132 and the thickness t5 of the inner dielectric pattern 152, respectively. Accordingly, the separation insulating pattern 160 may effectively insulate the outer word line 130 from the inner active pattern 140. However, embodiments are not limited thereto, and as another example, the thickness t6 of the separation insulating pattern 160 may be smaller than the thickness t4 of the outer dielectric pattern 132 and the thickness t5 of the inner dielectric pattern 152, respectively.

Additional active patterns (not shown) and additional word lines (not shown) may be further provided in the trench region. For example, additional active patterns (not shown) and additional word lines (not shown) may be provided in a region surrounded by the inner word line 150. An additional separation insulating pattern (not shown) may be further provided, may space a third active pattern from the second word line 50 and may insulate an additional active pattern (not shown) from an additional word line (not shown).

According to the concept of the present disclosure, the multi-gate structure 120 crossing the outer active pattern 110 may be provided, and thus, a plurality of transistors may be densely provided within a relatively narrow area. As a result, integration of the semiconductor device may be improved.

In addition, the outer channel region 110c of the outer active pattern 110 may be provided external to the trench TR along the wall of the trench TR, and the inner channel region 140c of the inner active pattern 140 may be provided within the trench region. Accordingly, even when the transistors of the semiconductor device are provided within a relatively narrow area when viewed in a plan view, a sufficiently long channel length of the transistors may be provided. As a result, the integration of the semiconductor device may be improved and electrical characteristics thereof may be improved.

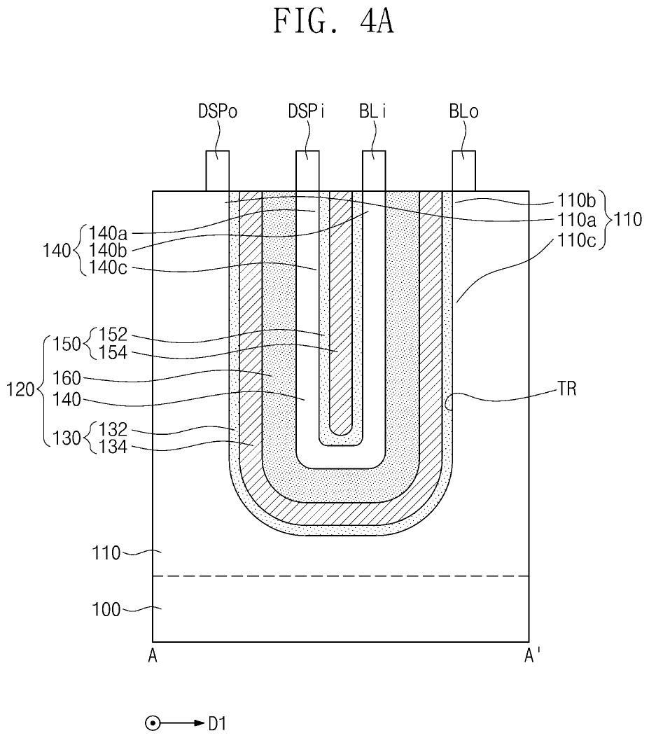

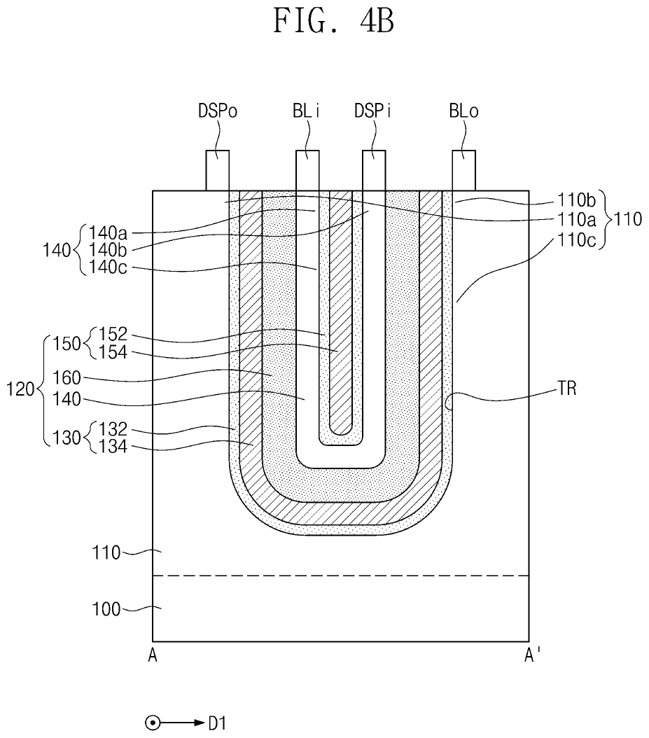

Hereinafter, semiconductor devices according to other embodiments will be described with reference to FIGS. 4A to 13. For convenience of description, descriptions of overlapping contents with the foregoing contents may be omitted.

FIGS. 4A and 4B are cross-sectional views corresponding to line A-A′ of FIG. 2.

Referring to FIGS. 4A and 4B, an outer bit line BLo and an outer data storage pattern DSPo may be provided on the outer active pattern 110. The outer bit line BLo and the outer data storage pattern DSPo may be electrically connected to the outer active pattern 110. The outer bit line BLo may be electrically connected to one of the pair of outer source/drain regions 110a and 110b of the outer active pattern 110, and the outer data storage pattern DSPo may be electrically connected to the other one. For example, each of the outer bit line BLo and the outer data storage pattern DSPo may be directly electrically connected to the outer active pattern 110. As another example, each of the outer bit line BLo and the outer data storage pattern DSPo may be electrically connected to the outer active pattern 110 through conductive patterns (not shown).

An inner bit line BLi and an inner data storage pattern DSPi may be provided on the inner active pattern 140. The inner bit line BLi and the inner data storage pattern DSPi may be electrically connected to the inner active pattern 140. The inner bit line BLi may be electrically connected to one of the pair of inner source/drain regions 140a and 140b of the inner active pattern 140, and the inner data storage pattern DSPi may be electrically connected to the other one. For example, each of the inner bit line BLi and the inner data storage pattern DSPi may be directly electrically connected to the inner active pattern 140. As another example, each of the inner bit line BLi and the inner data storage pattern DSPi may be electrically connected to the inner active pattern 140 through conductive patterns (not shown).

The outer bit line BLo, the outer data storage pattern DSPo, the inner bit line BLi, and the inner data storage pattern DSPi may be arranged in the first direction D1 (e.g., offset from one another in the first direction D1) and may be arranged in various orders without limitation.

For example, as shown in FIG. 4A, the outer and inner bit lines BLo and BLi may be provided adjacent to each other, and the outer and inner data storage patterns DSPo and DSPi may be provided adjacent to each other. The inner bit line BLi may be interposed between the outer bit line BLo and the inner data storage pattern DSPi, and the inner data storage pattern DSPi may be interposed between the inner bit line BLi and the outer data storage pattern DSPo.

As another example, as shown in FIG. 4B, the inner bit line BLi may be interposed between the outer and inner data storage patterns DSPo and DSPi, and the inner data storage pattern DSPi may be interposed between the outer and inner bit lines BLo and BLi. The outer bit line BLo and the inner bit line BLi may be spaced apart from each other with the inner data storage pattern DSPi interposed therebetween, and the outer data storage pattern DSPo and the inner data storage pattern DSPi may be spaced apart from each other with the inner bit line BLi interposed therebetween.

Each of the outer and inner data storage patterns DSPo and DSPi may be, for example, a capacitor including a lower electrode, a dielectric layer, and an upper electrode. In this case, the semiconductor device according to the present disclosure may include a dynamic random access memory (DRAM). Each of the outer and inner data storage patterns DSPo and DSPi may include, for example, a magnetic tunnel junction pattern. In this case, the semiconductor device according to the present disclosure may include magnetic random access memory (MRAM). As another example, each of the outer and inner data storage patterns DSPo and DSPi may include a phase change material or a variable resistance material. In this case, the semiconductor device according to the present disclosure may include phase-change random access memory (PRAM) or resistive random access memory (ReRAM). However, this is only exemplary and the present disclosure is not limited thereto, and each of the outer and inner data storage patterns DSPo and DSPi may include various structures and/or materials capable of storing data.

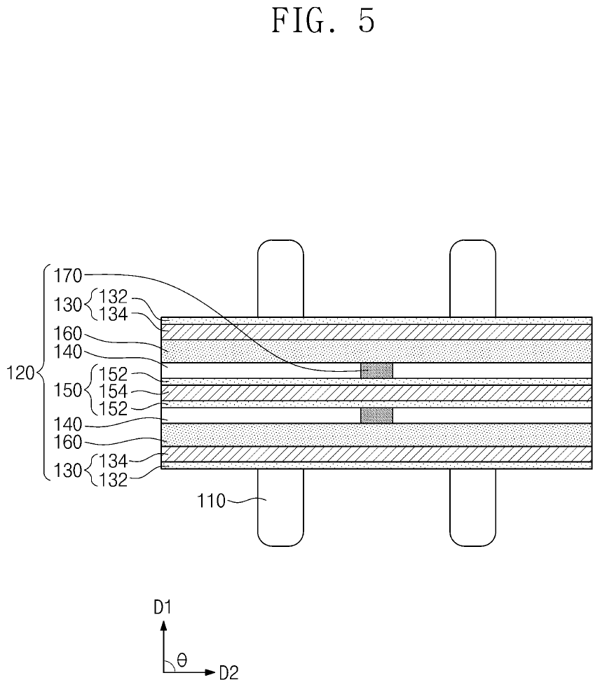

FIGS. 5 to 8 are plan views illustrating semiconductor devices according to some embodiments of the present disclosure.

Referring to FIGS. 5 to 8, a plurality of outer active patterns 110 may be provided. For example, an outer device isolation pattern (not shown) may surround each of the plurality of outer active patterns 110 and each of the plurality of active patterns may be spaced apart from each other. The plurality of outer active patterns 110 and a multi-gate structure 120 may be arranged in various numbers and shapes without limitation. Hereinafter, the number and shape of these according to some embodiments will be described in more detail. However, the embodiments of FIGS. 5 to 8 are not intended to be exhaustive and should be understood as an example for explaining the concept of the present disclosure. In other embodiments, the number and shape of the plurality of active patterns 110 and the multi-gate structure 120 may differ from those described in relation to FIGS. 5-8.

Referring to FIG. 5, outer active patterns 110 may be disposed adjacent to each other in the second direction D2 (e.g., may be offset from one another in the second direction). One multi-gate structure 120 may cross neighboring outer active patterns 110 of the plurality of active patterns. For example, one multi-gate structure 120 may include a plurality of inner active patterns 140, and each of the plurality of inner active patterns 140 may be provided on a corresponding one of the outer active patterns 110 (e.g., the inner active patterns 140 of one multi-gate structure 120 may be arranged in the second direction D2 such that each respective inner active pattern 140 corresponds to a respective outer active pattern 110). For example, the multi-gate structure 120 may further include an inner device isolation pattern 170, and the inner device isolation pattern 170 may separate each active pattern of the plurality of inner active patterns 140 from each other. However, this is only exemplary, and the plurality of inner active patterns 140 may be spaced apart from each other in various ways without limitation.

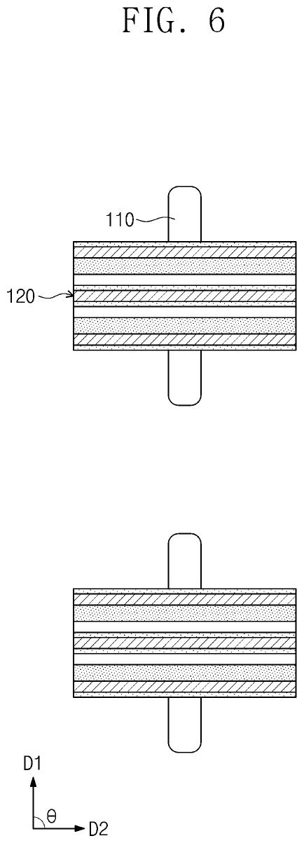

Referring to FIG. 6, outer active patterns 110 may be disposed adjacent to each other in the first direction D1 (e.g., repeating in the first direction and offset from one another in the first direction). A plurality of multi-gate structures 120 may be provided, and each of multi-gate structures 120 may cross a corresponding one of the outer active patterns 110 or a corresponding group of outer active patterns 110 of the plurality of outer active patterns 110.

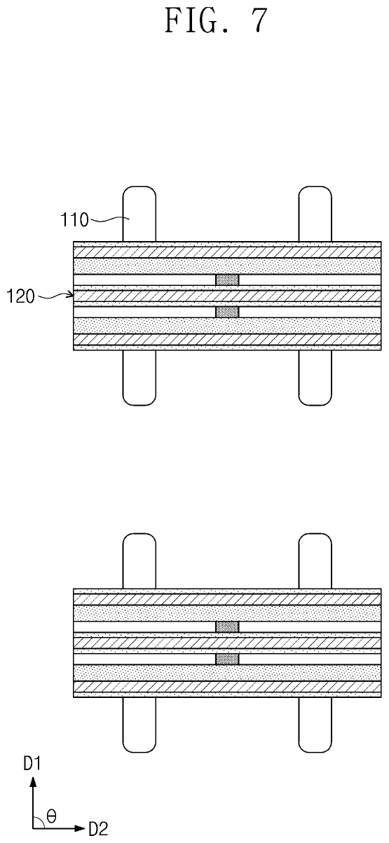

Referring to FIG. 7, outer active patterns 110 may be disposed adjacent to each other in the first direction D1 and the second direction D2. A plurality of multi-gate structures 120 may be provided and may be adjacent to each other in the first direction D1. Each of the multi-gate structures 120 may cross the outer active patterns 110 adjacent to each other in the second direction D2 among the outer active patterns 110. For example, each of the multi-gate structures 120 immediately adjacent in the first direction D1 may cross a corresponding one of the outer active patterns 110 immediately adjacent in the first direction D1.

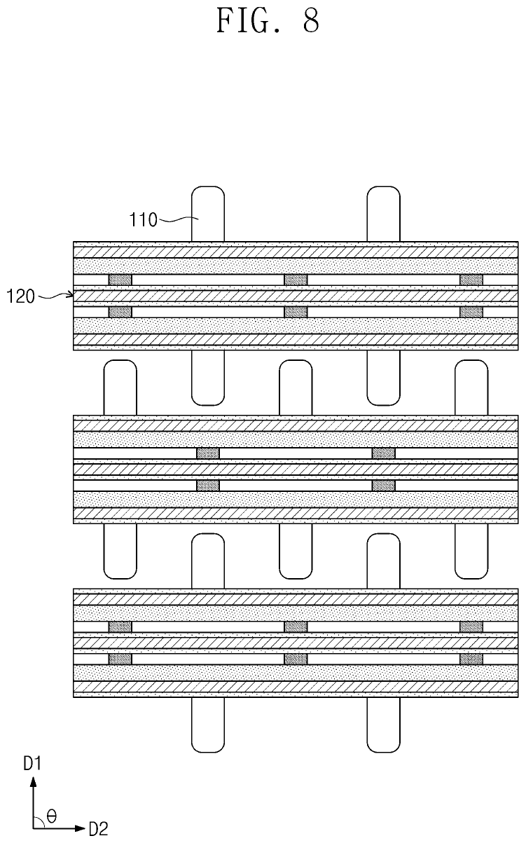

Referring to FIG. 8, outer active patterns 110 may be disposed adjacent to each other in the first direction D1 and the second direction D2. For example, a row of outer active patterns 110 neighboring in the second direction D2 may be provided, and another row of outer active patterns 110 neighboring in the first direction D1 may be provided. Another row of outer active patterns 110 may be shifted in the second direction D2 compared to the row of outer active patterns 110.

A plurality of multi-gate structures 120 may be provided and may be adjacent to each other in the first direction D1. For example, one of the multi-gate structures 120 immediately adjacent to each other in the first direction D1 may cross the row of outer active patterns 110 among the outer active patterns 110, and the other of the neighboring multi-gate structures 120 may cross another row of outer active patterns 110.

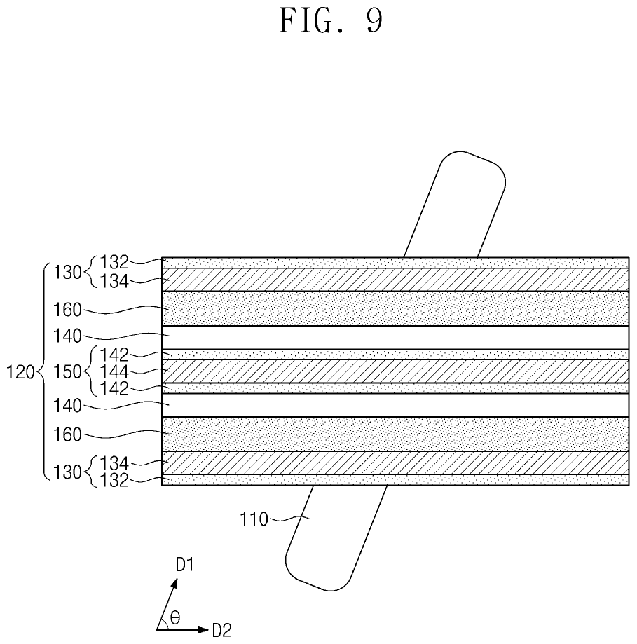

FIG. 9 is a plan view illustrating a semiconductor device according to some embodiments.

Referring to FIG. 9, an outer active pattern 110 may have a long axis extending in a first direction D1, and the multi-gate structure 120 may extend in a second direction D2. The first direction D1 and the second direction D2 may form a first angle θ with each other, and the first angle θ may be greater than 0° and less than 90°.

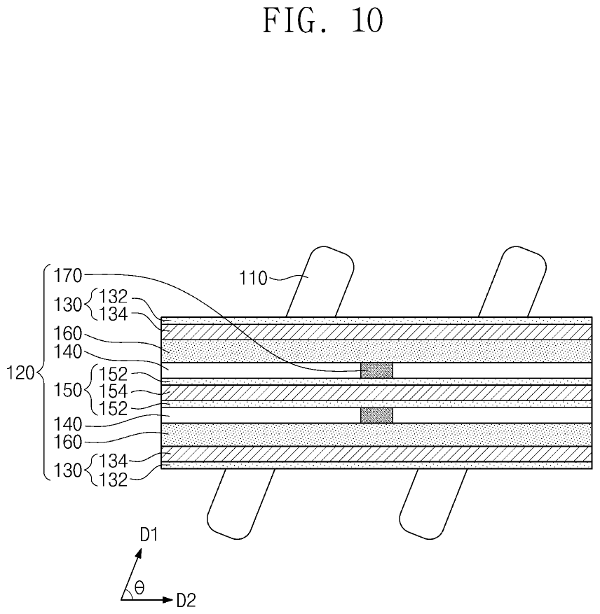

FIGS. 10 to 13 are plan views illustrating semiconductor devices according to some embodiments of the present disclosure.

Referring to FIGS. 10 to 13, a plurality of outer active patterns 110 described with reference to FIG. 9 may be provided. The plurality of outer active patterns 110 and the multi-gate structure 120 may be arranged in various numbers and shapes without limitation. Hereinafter, the number and shape of these will be described in more detail.

Referring to FIG. 10, outer active patterns 110 may be disposed adjacent to each other in the second direction D2. One multi-gate structure 120 may cross both of the outer active patterns 110 disposed adjacent to each other. For example, one multi-gate structure 120 may include a plurality of inner active patterns 140 (which may be arranged in a pattern in the second direction), and each of the plurality of inner active patterns 140 may be provided on a corresponding one of the outer active patterns 110.

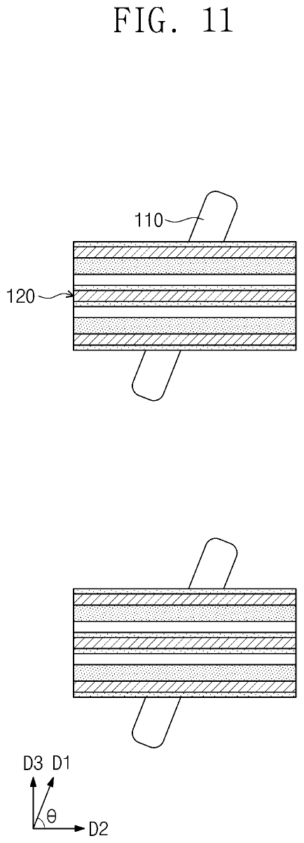

Referring to FIG. 11, outer active patterns 110 may be disposed adjacent to each other in a third direction D3. The third direction D3 may be a direction crossing the first direction D1 and the second direction D2. A plurality of multi-gate structures 120 may be provided, and each of the multi-gate structures 120 may cross a corresponding one of the outer active patterns 110.

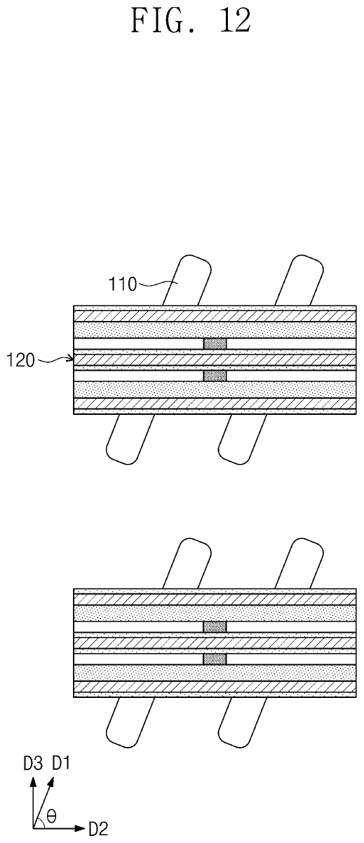

Referring to FIG. 12, outer active patterns 110 may be disposed adjacent to each other in the second direction D2 and the third direction D3. A plurality of multi-gate structures 120 may be provided and may be adjacent to each other in the third direction D3. Each of the multi-gate structures 120 may cross a group of the outer active patterns 110 that are adjacent to each other in the second direction D2 among the outer active patterns 110. For example, each of the multi-gate structures 120 immediately adjacent in the third direction D3 may cross a corresponding one of the outer active patterns 110 immediately adjacent in the third direction D3.

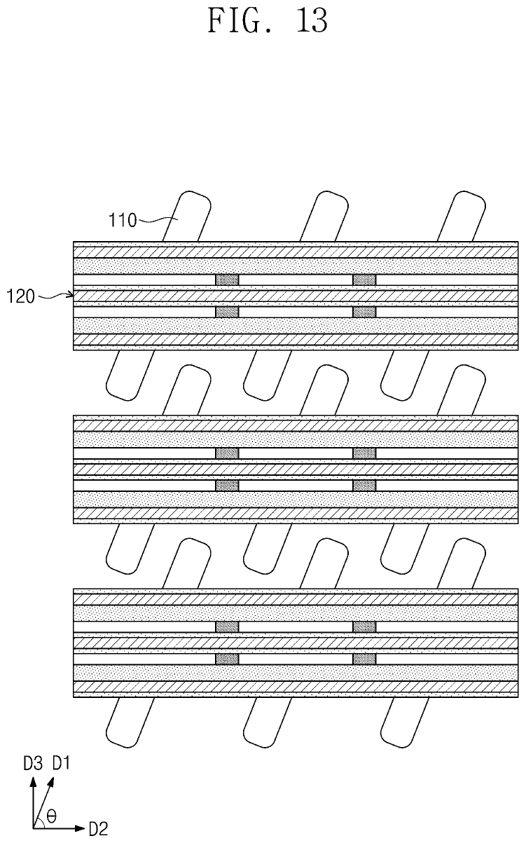

Referring to FIG. 13, outer active patterns 110 may be disposed adjacent to each other in the second direction D2 and the third direction D3. For example, ends of the outer active patterns 110 adjacent to each other in the third direction D3 may be disposed to be adjacent to each other in the second direction D2. A plurality of multi-gate structures 120 may be provided and may be adjacent to each other in the third direction D3. Each of the multi-gate structures 120 may cross the outer active patterns 110 adjacent to each other in the second direction D2 among the outer active patterns 110. For example, each of the multi-gate structures 120 immediately adjacent in the third direction D3 may cross a corresponding one of the outer active patterns 110 immediately adjacent in the third direction D3.

According to the concept of the present disclosure, the plurality of transistors may be densely provided within the relatively narrow area. As a result, the integration of the semiconductor device may be improved. In addition, even when the transistors of the semiconductor device are provided in the relatively narrow area, the word line may be buried in the trench TR to provide the sufficiently long channel lengths of the transistors. As a result, the integration of the semiconductor device may be improved and the electrical characteristics thereof may be improved.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. A semiconductor device comprising:
an outer active pattern on a substrate, the outer active pattern having a trench crossing the outer active pattern;
an outer word line covering a wall of the trench;
an inner active pattern covering the outer word line in the trench;
an inner word line covering the inner active pattern in the trench; and
a separation insulating pattern interposed between the outer word line and the inner active pattern in the trench,
wherein the outer word line and the inner word line are insulated from each other,
wherein the outer word line includes an outer gate electrode between the outer active pattern and the separation insulating pattern, and an outer dielectric pattern between the outer gate electrode and the outer active pattern,
wherein the inner word line includes an inner gate electrode covering the inner active pattern in the trench and an inner dielectric pattern between the inner gate electrode and the inner active pattern,
wherein the outer active pattern is spaced apart from the outer gate electrode with the outer dielectric pattern therebetween, and
wherein the inner active pattern is spaced apart from the inner gate electrode with the inner dielectric pattern interposed therebetween.

2. The semiconductor device of claim 1, wherein the separation insulating pattern separates the outer word line from the inner active pattern.

3. The semiconductor device of claim 1, wherein a thickness of the separation insulating pattern is greater than or substantially equal to both a thickness of the outer dielectric pattern and a thickness of the inner dielectric pattern, respectively.

4. The semiconductor device of claim 1, wherein the separation insulating pattern includes an insulating material.

5. The semiconductor device of claim 1, wherein the outer active pattern includes a pair of outer source/drain regions thereon, and
wherein the inner active pattern includes a pair of inner source/drain regions thereon.

6. The semiconductor device of claim 5, wherein the outer active pattern further includes an outer channel region extending along the wall between the pair of outer source/drain regions, and
wherein the inner active pattern further includes an inner channel region extending along the separation insulating pattern between the pair of inner source/drain regions.

7. The semiconductor device of claim 5, wherein the pair of inner source/drain regions are interposed between the pair of outer source/drain regions.

8. The semiconductor device of claim 1, wherein the inner active pattern includes a semiconductor material.

9. The semiconductor device of claim 1, wherein the outer active pattern surrounds the outer word line in the trench, and
wherein the inner active pattern surrounds the inner word line in the trench.

10. The semiconductor device of claim 1, wherein the outer active pattern extends in a first direction parallel to a lower surface of the substrate,
wherein the outer word line extends in a second direction parallel to the lower surface of the substrate, and
wherein an angle between the first direction and the second direction is greater than 0° and less than or equal to 90°.

11. The semiconductor device of claim 1, further comprising a plurality of outer active patterns, and
wherein the outer word line crosses each outer active pattern of the plurality of outer active patterns.

12. The semiconductor device of claim 11, wherein the inner word line crosses each outer active pattern of the plurality of outer active patterns.

13. A semiconductor device comprising:
an outer active pattern on a substrate, the outer active pattern having a trench crossing the outer active pattern;
an outer word line covering a wall of the trench;
an inner active pattern covering the outer word line in the trench;
an inner word line covering the inner active pattern in the trench;
a separation insulating pattern interposed between the outer word line and the inner active pattern in the trench;
an outer bit line and an outer data storage pattern electrically connected to the outer active pattern, respectively; and
an inner bit line and an inner data storage pattern electrically connected to the inner active pattern, respectively,
wherein the outer active pattern includes a pair of outer source/drain regions thereon,
wherein the inner active pattern includes a pair of inner source/drain regions thereon,
wherein the outer bit line is electrically connected to one of the pair of outer source/drain regions, and
wherein the inner bit line is electrically connected to one of the pair of inner source/drain regions.

14. The semiconductor device of claim 13, wherein the outer data storage pattern is electrically connected to the other one of the pair of outer source/drain regions, and
wherein the inner data storage pattern is electrically connected to the other one of the pair of inner source/drain regions.

15. The semiconductor device of claim 13, wherein the inner bit line and the inner data storage pattern are interposed between the outer active pattern and the outer data storage pattern.

16. The semiconductor device of claim 15, wherein the inner bit line is interposed between the outer bit line and the inner data storage pattern.

17. The semiconductor device of claim 15, wherein the inner data storage pattern is interposed between the outer bit line and the inner bit line.

18. The semiconductor device of claim 13, wherein each of the outer data storage pattern and the inner data storage pattern is a capacitor including a lower electrode, a dielectric layer, and an upper electrode.

19. A semiconductor device comprising:
a first active pattern on a substrate;
a second active pattern on the first active pattern;
a separation insulating pattern between the first active pattern and the second active pattern;
a first word line between the first active pattern and the separation insulating pattern; and
a second word line on the second active pattern,
wherein the first word line and the second word line are insulated from each other,
wherein the first word line includes a first gate electrode between the first active pattern and the separation insulating pattern, and a first dielectric pattern between the first active pattern and the first gate electrode,
wherein the second word line includes a second gate electrode on the second active pattern and a second dielectric pattern between the second active pattern and the second gate electrode, and
wherein a thickness of the separation insulating pattern is greater than or substantially equal to a thickness of the first dielectric pattern and a thickness of the second dielectric pattern, respectively.

20. The semiconductor device of claim 19, wherein the separation insulating pattern separates the first word line from the second active pattern.
